(19) United States
(12) Patent Application Publication
(10) Pub. No.: US 2024/0355792 A1
(43) Pub. Date: Oct. 24, 2024

(54) REVERSED OVERHANG MEMORY ON PACKAGE (MOP) ARCHITECTURE

(71) Applicant: Intel Corporation, Santa Clara, CA (US)

(72) Inventors: Poh Boon KHOO, Perai (MY); Jiun Hann SIR, Gelugor (MY); Eng Huat GOH, Air Itam (MY); Hooi San LAM, Air Itam (MY); Hazwani JAFFAR, Kepala Batas (MY)

(21) Appl. No.: 18/137,360

(22) Filed: Apr. 20, 2023

(51) Int. Cl. H01L 25/10; H01L 23/00; H01L 23/498; H01L 23/538; H10B 80/00

(52) U.S. Cl. CPC H01L 25/105; H01L 23/49816; H01L 23/49833; H01L 23/5385; H01L 23/5386; H01L 24/16; H01L 24/32; H01L 24/48; H01L 24/73; H10B 80/00; H01L 23/49838; H01L 2224/16225; H01L 2224/32225; H01L 2224/48225; H01L 2224/73204; H01L 2924/1427; H01L 2924/1431; H01L 2924/1436

(57) ABSTRACT

Embodiments disclosed herein include electronic packages. In an example, an electronic package includes a package substrate. A die is coupled to the package substrate. The electronic package also includes a memory stack. The memory stack includes a die stack structure coupled to a substrate. The substrate is coupled to and is extending laterally beyond the package substrate. The die stack structure includes a stack of dies and through vias in a mold layer. The die stack structure is laterally spaced apart from the package substrate.

### TECHNICAL FIELD

Embodiments of the present disclosure relate to electronic packages, and more particularly to packaging architectures that include memory stacks.

### BACKGROUND

Memory on package (MoP) architectures have been used in order achieve the best DDR performance and smallest SoC XY footprint. However, there are a few intrinsic issues that arise with existing MoP architectures. One issue is an increased Z-height. The addition of a tall memory package (e.g., a stack of memory dies on a memory package substrate) increases the Z-height of the device. For example, Z-heights may be increased by between 300 μm and 350 μm in some architectures. In some instances, the increase in the Z-height is mitigated by using a coreless package architecture. However, the use of a coreless architecture is an extremely expensive solution.

Additionally, the MoP architecture results in an overall SoC package XY form factor that is substantially large. This is due to the need to include a stiffener in order to control warpage of the package substrate. In some instances, a combination stiffener and integrated heat spreader (IHS) is used in order to control warpage and improve thermal performance. However, such architectures are expensive solutions.

### BRIEF DESCRIPTION OF THE DRAWINGS

FIG. 1 is a cross-sectional illustration of a memory on package (MoP) architecture where the memory die stacks are provided on a package substrate that is connected to the main package substrate.

FIG. 2A is a plan view illustration of a MoP architecture with a mold layer over and around the memory die stacks and an opening in the mold layer to accommodate a die module.

FIG. 2B is a cross-sectional illustration of the package substrate with memory die stacks that are embedded in the mold layer.

FIG. 3 illustrates a cross-sectional view of a system including a reversed overhang memory on package structure, in accordance with an embodiment of the present disclosure.

FIGS. 4A-4D illustrate cross-sectional views representing various operations in a method of fabricating a memory stack, in accordance with an embodiment of the present disclosure.

FIGS. 5A-5D illustrates cross-sectional views representing various operations in a method of fabricating a system including a reversed overhang memory on package structure, in accordance with an embodiment of the present disclosure.

FIG. 6 illustrates a cross-sectional view of a system including a reversed overhang memory on package structure, in accordance with an embodiment of the present disclosure.

FIG. 7A illustrates a cross-sectional view of a system including a standard memory on package structure.

FIG. 7B illustrates a cross-sectional view of a system including a reversed overhang memory on package structure, in accordance with an embodiment of the present disclosure.

FIG. 8 is a schematic of a computing device built in accordance with an embodiment.

### EMBODIMENTS OF THE PRESENT DISCLOSURE

Described herein are packaging architectures that include memory stacks, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

To provide context, existing memory on package structures are known to have three major trade-offs. There can be an increase of Package Z height due to taller memory components. There can be an increase of Package Size due to housing memory components. There can be complicated thermal solution due to different surface height between CPU/GT die and memory components.

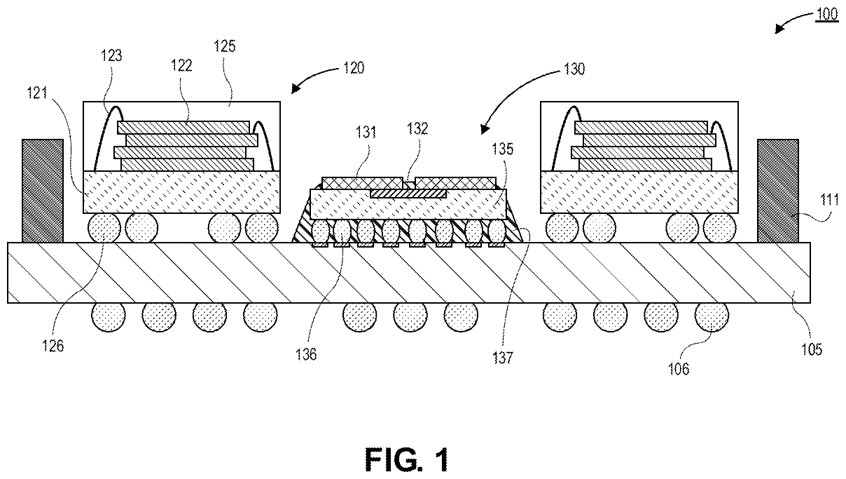

For comparative purposes, FIG. 1 is a cross-sectional illustration of an electronic package 100 used to provide context for embodiments described herein. The electronic package 100 includes an architecture where memory die stacks 120 are attached to a package substrate 105 adjacent to a die module 130. The package substrate 105 may include bumps 106 on a backside of the package substrate 105. The memory die stacks 120 and the die module 130 may be provided on the front side of the package substrate 105. For example, the memory die stack 120 may include bumps 126 that connect to the package substrate 105, and the die module 130 may include bumps 136 that connect to the package substrate 105. An underfill 137 may be provided around the bumps 136. While not shown, an underfill may also surround the bumps 126 between the memory die stack 120 and the package substrate 105.

In an embodiment, a mold layer 125 may be provided over and around the memory die stacks 120. The mold layer 125 may be an epoxy molding material or any other suitable material. In an embodiment, a thickness of the mold layer 125 may be greater than a height of the memory die stacks 120. The mold layer 125 may also embed the wire bonds 123.

The die module 130 may include any number of dies 131 in any architecture. For example, a pair of dies 131 may be coupled to each other through a bridge 132 embedded in an interposer 135. The die module 130 may be a system on a chip (SoC) or any other type of die or dies. The die module 130 may be communicatively coupled to the memory die stacks 120 through routing (not shown) on and/or in the package substrate 105.

The memory die stacks 120 may include a memory package substrate 121. A stack of memory dies 122 may be provided over the memory package substrate 121. The memory dies 122 may be electrically coupled to the memory package substrate 121 through wire bonds 123. Due to the presence of the memory package substrate 121, the length of the routing from the memory dies 122 to the die module 130 is long. This leads to larger delays and signal integrity issues. Additionally, the memory package substrate 121 results in an increase in the Z-height of the electronic package 100. A stiffener 111 may also be needed in order to mitigate warpage issues. The presence of the stiffener 111 increase the X-Y dimensions of the electronic package 100.

Accordingly, memory on package (MoP) architectures, such as the one shown in FIG. 1, have intrinsic drawbacks, such as increased Z-height and increased X-Y form factor. To provide further context and comparison, MoP architectures that have a smaller Z-height and reduced X-Y form factor are described, which may be made without relying on coreless package substrates.

Particularly, a package substrate is provided and memory die stacks are provided directly on the package substrate. The memory dies may be coupled to the package substrate directly through wire bonds. As such, there is no need for a memory package substrate between the memory dies and the main package substrate. This results in a decrease in the Z-height of the device. Additionally, the X-Y form factor is reduced by the use of mold layer around the memory die stacks. The mold layer allows for the elimination of the stiffener in some embodiments. That is, the mold layer improves the stiffness of the package substrate, and there may not be a need for a stiffener. However, in other embodiments, a stiffener may also be included. In such an embodiment, the stiffener may also be embedded in the mold layer.

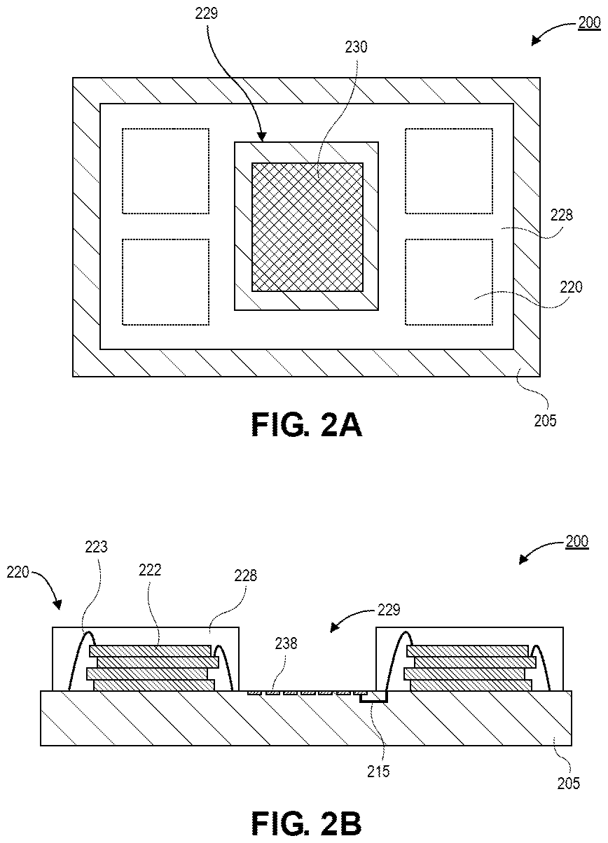

Referring now to FIG. 2A, for comparative purposes, a plan view illustration of an electronic package 200 is shown. The electronic package 200 may include a package substrate 205. The package substrate 205 may include a core and buildup layers over and under the core. Depending on the routing needs, the package substrate 205 may be a six layer package substrate 205, an eight layer package substrate 205, or a ten layer package substrate 205. It is to be appreciated that embodiments disclosed herein may include package substrates 205 with any number of routing layers. Since a core is used, the cost of the package substrate 205 is reduced and the stiffness is increased (compared to coreless architectures).

In an embodiment, a mold layer 228 may be provided over a top surface of the package substrate 205. The mold layer 228 may be an epoxy molding material or any other suitable material. In an embodiment, the mold layer 228 is an electrically insulating material. In an embodiment, the mold layer 228 has an outer perimeter that is smaller than an outer perimeter of the package substrate 205. However, the outer perimeter of the mold layer 228 may be substantially equal to the outer perimeter of the package substrate 205 in other embodiments. In an embodiment, the mold layer 228 may have an opening 229. The opening 229 may be sized to receive a die module 230. While shown as a single die in FIG. 2A, it is to be appreciated that the die module 230 may include one or more dies. The die module 230 may also include an interposer for coupling multiple dies together.

In an embodiment, a plurality of memory die stacks 220 may be embedded in the mold layer 228. For example, the die stacks 220 in FIG. 2A are shown with dashed lines in order to illustrate that the memory die stacks 220 are provided below the top surface of the mold layer 228. The memory die stacks 220 may be directly coupled to the package substrate 205. That is, the memory die stacks 220 may not need a memory package substrate between the memory dies and the package substrate 205, as is the case in the example shown in FIG. 1. This reduces the Z-height of the electronic package 200. Additionally, the omission of the memory package substrate reduces the length of the routing between the die module 230 and the memory die stack 220. In the illustrated embodiment, there are four memory die stacks 220. However, it is to be appreciated that any number of memory die stacks 220 may be used in accordance with various embodiments. For example, there may be one or more memory die stacks 220 in the electronic package 200.

Referring now to FIG. 2B, a cross-sectional illustration of an electronic package 200 is shown, in accordance with an embodiment. As shown, the memory die stacks 220 are directly coupled to the package substrate 205. That is, a bottommost memory die 222 is directly contacting the package substrate 205. In an embodiment, the memory dies 222 may be electrically coupled to pads (not shown) on the package substrate 205 by wire bonds 223. As used herein, a memory die stack 220 may refer to a stack of one or more memory dies 222. In a particular embodiment, four memory dies 222 are included in the memory die stack 220. The individual memory dies 222 may be stacked in an offset pattern. The offset pattern allows for the top surface of each of the memory dies 222 to be exposed in order to receive the wire bonds.

The memory die stacks 220 may be embedded in a mold layer 228. The mold layer 228 may be around sidewalls and top surfaces of the memory dies 222. The wire bonds 223 may also be embedded in the mold layer 228. In the illustrated embodiment, the mold layer 228 appears as two separate regions (one region around each of the memory die stacks 220). However, it is to be appreciated that the two separate regions may be coupled together by portions of the mold layer 228 that are provided outside of the plane of FIG. 2B.

An opening 229 may be provided through the mold layer 228. The opening 229 may be provided in the middle of the mold layer 228 in order to accommodate the die module (not shown in FIG. 2B). In an embodiment, pads 238 may be provided in the opening 229. The die module may be connected to the package substrate 205 through the pads 238. In an embodiment, certain ones of the pads 238 may be coupled to the wire bonds 223 of the memory die stack 220 by routing 215 in and/or on the package substrate 205.

It is to be appreciated that although the structures of FIGS. 2A and 2B provide improvements over the structure of FIG. 1, other approaches and architectures can be implemented to provide improvements over the structure of FIG. 1. In another aspect, in accordance with embodiments of the present disclosure, a dynamic random access memory (DRAM) package is reversely mounted to a system on chip (SOC) package through an extended DRAM substrate. In one embodiment, the DRAM substrate is connected to the SOC package through a copper plated through hole aligning to a pre-solder on the SOC package. In an embodiment, Package Z height can be further reduced by eliminating the DRAM solder ball. In an embodiment, a copper pillar is formed at the DRAM to allow DRAM power direct feed from a voltage regulator (VR)/power management integrated circuit (VR/PMIC).

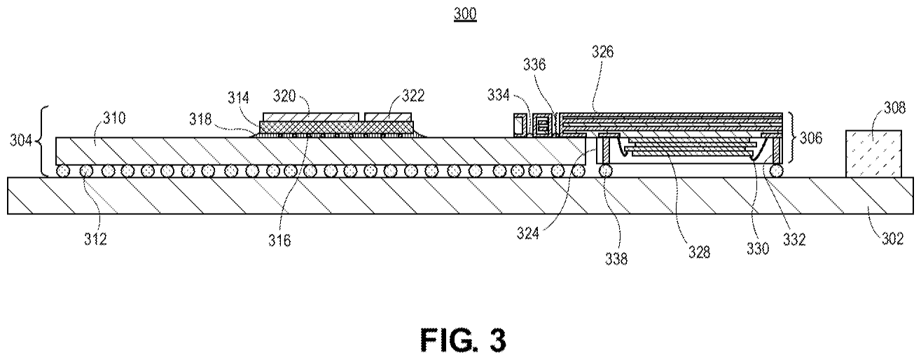

As an example, FIG. 3 illustrates a cross-sectional view of a system including a reversed overhang memory on package structure, in accordance with an embodiment of the present disclosure.

Referring to FIG. 3, a system 300 includes a board 302, such as a mother board. A reversed overhang memory on package structure 304 is coupled to the board 302. The reversed overhang memory on package structure 304 includes a memory stack 306, such as a DRAM memory stack. The system 300 can also include a voltage regulator (VR) 308 coupled to the board 302, which can be coupled to the memory stack 306. The reversed overhang memory on package structure 304 also includes a package substrate 310, which may include layers of traces and vias therein. The package substrate 310 can be electrically coupled to the board 302 by conductive bumps and/or solder balls 312. A die 314, such as a processor die or memory die or base die, can be coupled to the package substrate 310, e.g., by conductive bumps and/or solder balls 316 which can be surrounded by an underfill layer 318. Additional dies 320 and 322, such as processor dies or memory dies, can be coupled to the die 314. The memory stack 306 includes a die stack structure 324 coupled to a substrate 326, such as a DRAM substrate. The die stack structure 324 can include a stack of dies 328, such as DRAM dies, together with wire bonds 330 and through vias 332, e.g., all in a mold layer. The substrate 326 can be coupled to the package substrate 310 using pre-solder 334 and plated through holes 336. The memory stack 306 can be electrically coupled to the board 302 by conductive bumps and/or solder balls 338. In an embodiment, the substrate 326 extends laterally beyond the package substrate 310, and the die stack structure 324 of the memory stack 306 is laterally spaced apart from the package substrate 310. The resulting architecture can be referred to as an overhang structure. It is to be appreciate that although only one overhang memory stack 306 is depicted, additional overhang memory stacks can be included as arranged around die 314, e.g., in a layout such as described in association with FIGS. 2A and 2B.

Advantages to implementing embodiments disclosed herein can be the achievement of smaller Package Z height and/or smaller package size. Embodiments can be implemented to provide a straight forward thermal solution for top dies (CPU/GT/SOC). It may be the case that no pedestal heatsink is needed. Embodiments can be implemented to achieve low power and improve power delivery efficiency with direct power feed from VR/PMIC. Embodiments can be detectable as including a DRAM substrate mounted reversely on the package.

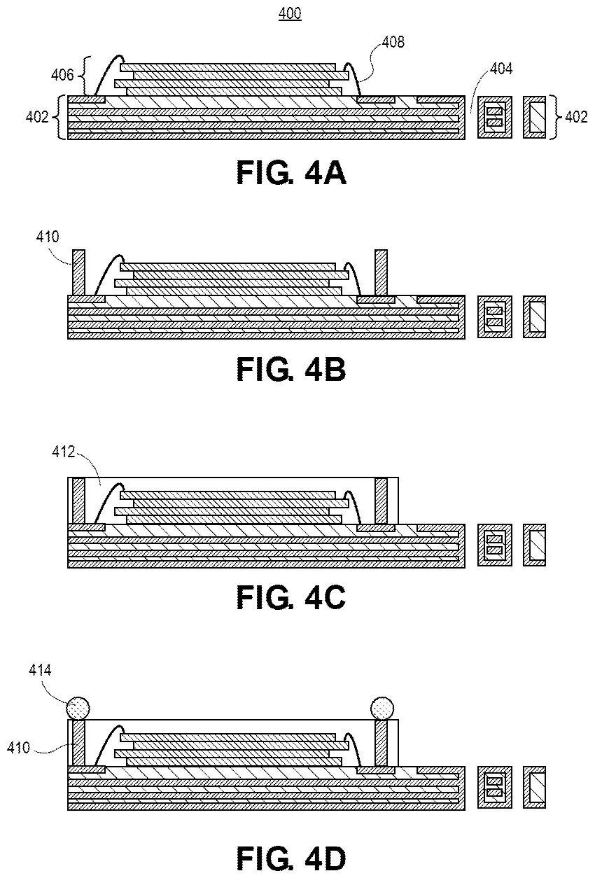

As an exemplary fabrication scheme, FIGS. 4A-4D illustrate cross-sectional views representing various operations in a method of fabricating a memory stack, in accordance with an embodiment of the present disclosure.

Referring to FIG. 4A, a starting structure 400 includes a stack of dies 406, such as DRAM dies, coupled to a substrate 402 with wire bonds 408. The substrate 402 can include conductive vias and traces and can include plated through holes 404 therein. Conductive posts or through vias 410 are then formed on the substrate 402 adjacent to the stack of dies 406, as is depicted in FIG. 4B. Referring to FIG. 4C, a mold compound 412, such as an epoxy mold, is formed to laterally surround the stack of dies 406 and the conductive posts or through vias 410. Conductive bumps and/or solder balls 414 can then be formed on the conductive posts or through vias 410, e.g., for eventual electrical coupling to a board, as is depicted in FIG. 4D.

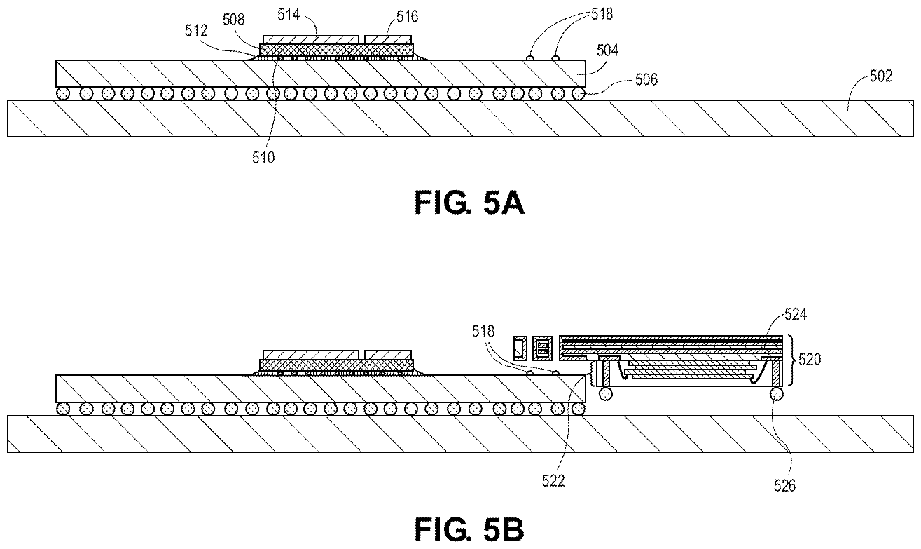

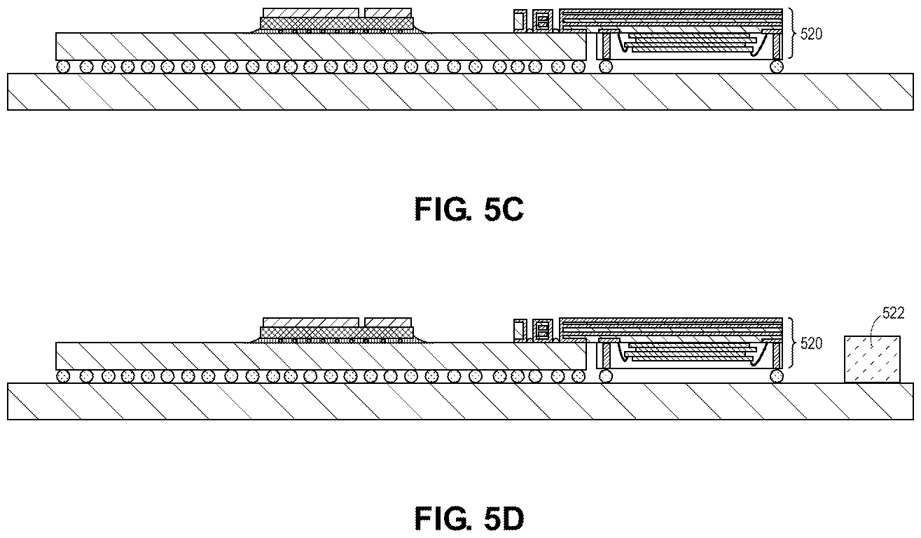

As an exemplary processing scheme, FIGS. 5A-5D illustrates cross-sectional views representing various operations in a method of fabricating a system including a reversed overhang memory on package structure, in accordance with an embodiment of the present disclosure.

Referring to FIG. 5A, a staring structure includes a board 502, such as a mother board. A package substrate 504 is electrically coupled to the board 502 by conductive bumps and/or solder balls 506. A die 508, such as a processor die or memory die or base die, is coupled to the package substrate 504, e.g., by conductive bumps and/or solder balls 510 which can be surrounded by an underfill layer 512. Additional dies 514 and 516, such as processor dies or memory dies, can be coupled to the die 508. Pre-solder structures 518 are formed on the package substrate 504.

Referring to FIG. 5B, a memory stack 520, such as a DRAM memory stack, is coupled to the pre-solder structures 518, e.g., by plated through holes in a substrate 524 of the memory stack 520. The memory stack 520 can include a die stack structure 522 coupled to substrate 524. The die stack structure 522 can include a stack of dies, such as DRAM dies, together with wire bonds and through vias, e.g., all in a mold layer. Conductive bumps and/or solder balls 526 can be formed on the conductive posts or through vias, e.g., for eventual electrical coupling to a board.

Referring to FIG. 5C, a reflow operation can be formed to electrically couple the memory stack 520 and the pre-solder structures 518. Other components 522, such as a voltage regulator can also be coupled to the board 502 and, possibly to the memory stack 520, as is depicted in FIG. 5D. It is to be appreciate that although only one overhang memory stack 520 is depicted, additional overhang memory stacks can be included as arranged around die 508, e.g., in a layout such as described in association with FIGS. 2A and 2B.

With reference again to FIGS. 5A-5D, in an embodiment, connection between a DRAM package (e.g., 524) and an SOC package (e.g., 504) are performed without using solder balls. Pre-solder on the SOC package can be used to lock and align to a copper plated through hole on the DRAM substrate, and can further reduce the overall Z-height.

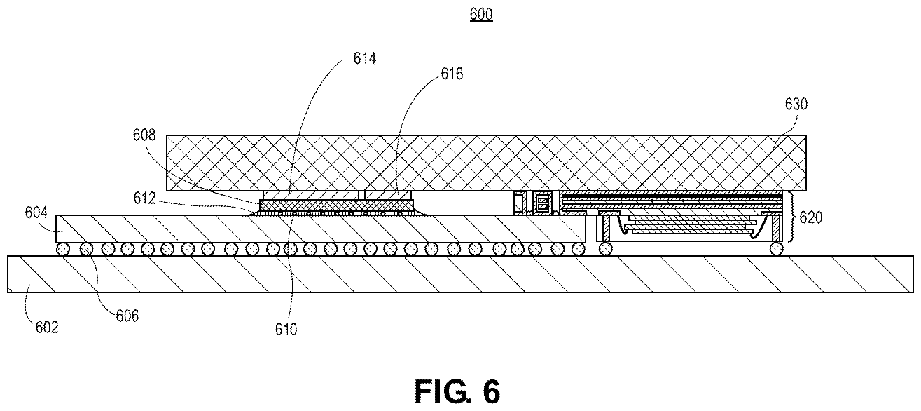

Embodiments may enable the use of a flat heat spreader. As an example, FIG. 6 illustrates a cross-sectional view of a system including a reversed overhang memory on package structure, in accordance with an embodiment of the present disclosure.

Referring to FIG. 6, a system 600 includes a board 602, such as a mother board. A reversed overhang memory on package structure is coupled to the board 602. The reversed overhang memory on package structure includes a memory stack 620, such as a DRAM memory stack. The reversed overhang memory on package structure also includes a package substrate 604, which may include layers of traces and vias therein. The package substrate 604 can be electrically coupled to the board 602 by conductive bumps and/or solder balls 606. A die 608, such as a processor die or memory die or base die, can be coupled to the package substrate 604, e.g., by conductive bumps and/or solder balls 610 which can be surrounded by an underfill layer 612. Additional dies 614 and 616, such as processor dies or memory dies, can be coupled to the die 608. The memory stack 620 can include a die stack structure coupled to a substrate, such as a DRAM substrate. The die stack structure can include a stack of dies, such as DRAM dies, together with wire bonds and through vias, e.g., all in a mold layer. The substrate of the memory stack 620 can be coupled to the package substrate 604 using pre-solder and plated through holes. The memory stack 620 can be electrically coupled to the board 602 by conductive bumps and/or solder balls. A heat spreader or heat sink 630, such as a copper slug or dummy silicon die, can be included and, in one embodiment, can have a flat interface with the underlying structure, as is depicted. It is to be appreciate that although only one overhang memory stack 620 is depicted, additional overhang memory stacks can be included as arranged around die 608, e.g., in a layout such as described in association with FIGS. 2A and 2B.

It is to be appreciated that embodiments described herein can be implemented to achieve low power and improve power delivery efficiency with direct power feed/shorter path from VR/PMIC.

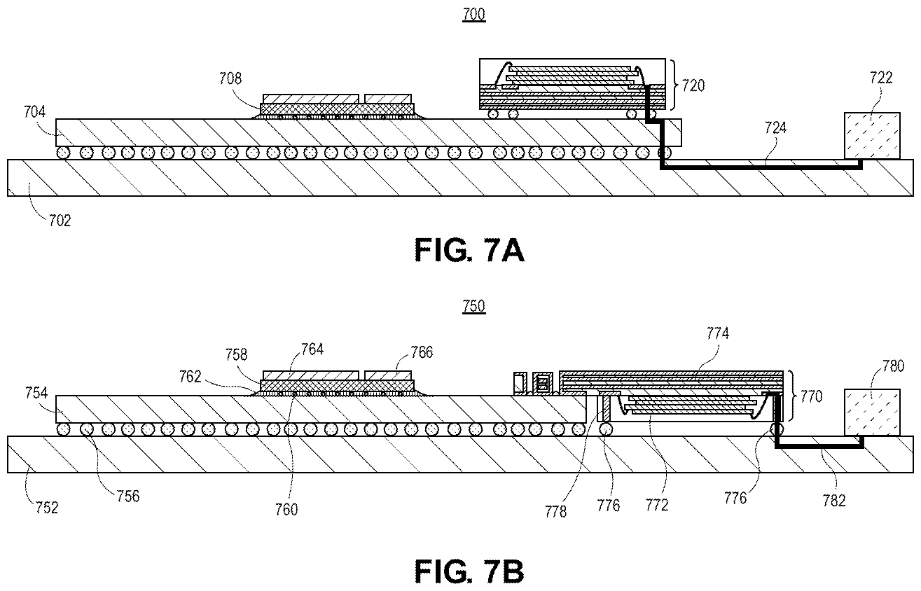

For comparative purposes, FIG. 7A illustrates a cross-sectional view of a system including a standard memory on package structure.

Referring to FIG. 7, a system 700 includes a board 702. A package substrate 704 is coupled to the board 702. A die 708 is coupled to the package substrate 704. A memory stack 720 is also coupled to the package substrate 704. A voltage regulator 722 is coupled to the board 702. An electrical path 724 is from the voltage regulator 722 to the memory stack 720.

In contrast to FIG. 7A, FIG. 7B illustrates a cross-sectional view of a system including a reversed overhang memory on package structure, in accordance with an embodiment of the present disclosure.

Referring to FIG. 7B, a system 750 includes a board 752, such as a mother board. A reversed overhang memory on package structure is coupled to the board 752. The reversed overhang memory on package structure includes a memory stack 770, such as a DRAM memory stack. The reversed overhang memory on package structure also includes a package substrate 754, which may include layers of traces and vias therein. The package substrate 754 can be electrically coupled to the board 752 by conductive bumps and/or solder balls 756. A die 758, such as a processor die or memory die or base die, can be coupled to the package substrate 754, e.g., by conductive bumps and/or solder balls 760 which can be surrounded by an underfill layer 762. Additional dies 764 and 766, such as processor dies or memory dies, can be coupled to the die 758. The memory stack 770 can include a die stack structure coupled to a substrate 774, such as a DRAM substrate. The die stack structure can include a stack of dies 772, such as DRAM dies, together with wire bonds and through vias 778, e.g., all in a mold layer. The substrate 774 of the memory stack 770 can be coupled to the package substrate 754 using pre-solder and plated through holes. The memory stack 770 can be electrically coupled to the board 752 by conductive bumps and/or solder balls 776. A voltage regulator 780 is coupled to the board 752. An electrical path 782 is from the voltage regulator 780 to the memory stack 770. The electric path 782 is substantially shorter than the electrical path 724 of FIG. 7A. It is to be appreciate that although only one overhang memory stack 770 is depicted, additional overhang memory stacks can be included as arranged around die 758, e.g., in a layout such as described in association with FIGS. 2A and 2B.

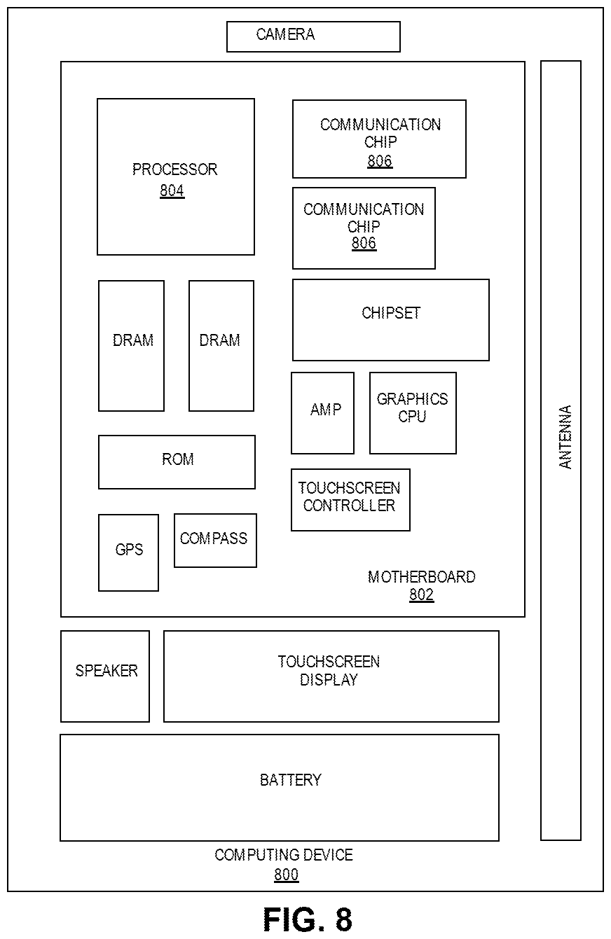

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic system that includes one or more reversed overhang memory on package structures, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic system that includes one or more reversed overhang memory on package structures, in accordance with embodiments described herein.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example embodiment 1: An electronic package includes a package substrate. A die is coupled to the package substrate. The electronic package also includes a memory stack. The memory stack includes a die stack structure coupled to a substrate. The substrate is coupled to and is extending laterally beyond the package substrate. The die stack structure includes a stack of dies and through vias in a mold layer. The die stack structure is laterally spaced apart from the package substrate.

Example embodiment 2: The electronic package of example embodiment 1, wherein the substrate of the memory stack is coupled to the package substrate by plated through holes in the substrate of the memory stack and solder on the package substrate.

Example embodiment 3: The electronic package of example embodiment 1 or 2, wherein the memory stack is electrically coupled to the board by conductive bumps or solder balls in contact with the through vias in the die stack structure.

Example embodiment 4: The electronic package of example embodiment 1, 2 or 3, wherein the substrate of the memory stack extends laterally beyond the die stack structure of the memory stack in only one direction.

Example embodiment 5: The electronic package of example embodiment 1, 2, 3 or 4, wherein the memory stack is a DRAM memory stack.

Example embodiment 6: The electronic package of example embodiment 1, 2, 3, 4 or 5, wherein the die is coupled to the package substrate by conductive bumps or solder balls surrounded by an underfill layer.

Example embodiment 7: A memory stack includes a substrate, and a die stack structure coupled to the substrate. The die stack structure includes a stack of dies and through vias in a mold layer. The substrate extends laterally beyond the die stack structure in only one direction.

Example embodiment 8: The memory stack of example embodiment 7, wherein the die stack structure further includes wire bonds in the mold layer.

Example embodiment 9: A system includes a board, and a reversed overhang memory on package structure coupled to the board. The reversed overhang memory on package structure includes a package substrate, a die coupled to the package substrate, and a memory stack. The memory stack includes a die stack structure coupled to a substrate, the substrate coupled to and extending laterally beyond the package substrate. The die stack structure includes a stack of dies and through vias in a mold layer, and the die stack structure is laterally spaced apart from the package substrate.

Example embodiment 10: The system of example embodiment 9, wherein the substrate of the memory stack is coupled to the package substrate by plated through holes in the substrate of the memory stack and solder on the package substrate.

Example embodiment 11: The system of example embodiment 9 or 10, wherein the memory stack is electrically coupled to the board by conductive bumps or solder balls in contact with the through vias in the die stack structure.

Example embodiment 12: The system of example embodiment 9, 10 or 11, wherein the substrate of the memory stack extends laterally beyond the die stack structure of the memory stack in only one direction.

Example embodiment 13: The system of example embodiment 9, 10, 11 or 12, wherein the memory stack is a DRAM memory stack.

Example embodiment 14: The system of example embodiment 9, 10, 11, 12 or 13, further including a voltage regulator coupled to the board.

Example embodiment 15: The system of example embodiment 14, wherein the voltage regulator is electrically coupled to the memory stack through the board.

Example embodiment 16: The system of example embodiment 9, 10, 11, 12, 13, 14 or 15, wherein the package substrate is electrically coupled to the board by conductive bumps or solder balls.

Example embodiment 17: The system of example embodiment 9, 10, 11, 12, 13, 14, 15 or 16, wherein the die is a base die.

Example embodiment 18: The system of example embodiment 9, 10, 11, 12, 13, 14, 15, 16 or 17, wherein the die is coupled to the package substrate by conductive bumps or solder balls surrounded by an underfill layer.

Example embodiment 19: The system of example embodiment 9, 10, 11, 12, 13, 14, 15, 16, 17 or 18, further including one or more additional dies coupled to the die.

Example embodiment 20: The system of example embodiment 9, 10, 11, 12, 13, 14, 15, 16, 17, 18 or 19, wherein the die stack structure further includes wire bonds in the mold layer.

What is claimed is:

1. An electronic package, comprising:
a package substrate;
a die coupled to the package substrate; and
a memory stack, the memory stack comprising a die stack structure coupled to a substrate, the substrate coupled to and extending laterally beyond the package substrate, the die stack structure comprising a stack of dies and through vias in a mold layer, and the die stack structure laterally spaced apart from the package substrate.

2. The electronic package of claim 1, wherein the substrate of the memory stack is coupled to the package substrate by plated through holes in the substrate of the memory stack and solder on the package substrate.

3. The electronic package of claim 1, wherein the memory stack is electrically coupled to the board by conductive bumps or solder balls in contact with the through vias in the die stack structure.

4. The electronic package of claim 1, wherein the substrate of the memory stack extends laterally beyond the die stack structure of the memory stack in only one direction.

5. The electronic package of claim 1, wherein the memory stack is a DRAM memory stack.

6. The electronic package of claim 1, wherein the die is coupled to the package substrate by conductive bumps or solder balls surrounded by an underfill layer.

7. A memory stack, comprising:
a substrate; and
a die stack structure coupled to the substrate, the die stack structure comprising a stack of dies and through vias in a mold layer, wherein the substrate extends laterally beyond the die stack structure in only one direction.

8. The memory stack of claim 7, wherein the die stack structure further comprises wire bonds in the mold layer.

9. A system, comprising:
a board; and
a reversed overhang memory on package structure coupled to the board, the reversed overhang memory on package structure comprising:
a package substrate;
a die coupled to the package substrate; and
a memory stack, the memory stack comprising a die stack structure coupled to a substrate, the substrate coupled to and extending laterally beyond the package substrate, the die stack structure comprising a stack of dies and through vias in a mold layer, and the die stack structure laterally spaced apart from the package substrate.

10. The system of claim 9, wherein the substrate of the memory stack is coupled to the package substrate by plated through holes in the substrate of the memory stack and solder on the package substrate.

11. The system of claim 9, wherein the memory stack is electrically coupled to the board by conductive bumps or solder balls in contact with the through vias in the die stack structure.

12. The system of claim 9, wherein the substrate of the memory stack extends laterally beyond the die stack structure of the memory stack in only one direction.

13. The system of claim 9, wherein the memory stack is a DRAM memory stack.

14. The system of claim 9, further comprising:
a voltage regulator coupled to the board.

15. The system of claim 14, wherein the voltage regulator is electrically coupled to the memory stack through the board.

16. The system of claim 9, wherein the package substrate is electrically coupled to the board by conductive bumps or solder balls.

17. The system of claim 9, wherein the die is a base die.

18. The system of claim 9, wherein the die is coupled to the package substrate by conductive bumps or solder balls surrounded by an underfill layer.

19. The system of claim 9, further comprising:
one or more additional dies coupled to the die.

20. The system of claim 9, wherein the die stack structure further comprises wire bonds in the mold layer.
